(19) United States
(12) Patent Application Publication
(10) Pub. No.: US 2011/0174363 A1
(43) Pub. Date: Jul. 21, 2011

(54) Control of Composition Profiles in Annealed CIGS Absorbers

(75) Inventor: Mariana Rodica Munteanu, Santa Clara, CA (US)

(73) Assignee: AQT Solar, Inc., Sunnyvale, CA (US)

(21) Appl. No.: 13/005,443

(22) Filed: Jan. 12, 2011

Related U.S. Application Data
(60) Provisional application No. 61/297,144, filed on Jan. 21, 2010.

(51) Int. Cl. H01L 31/06; H01L 31/0352

(52) U.S. Cl. 136/255; 438/94; 438/95; 257/E31.032

(57) ABSTRACT

Particular embodiments of the present disclosure relate to the use of sputtering, and more particularly magnetron sputtering, in forming absorber structures, and particular multilayer absorber structures, that are subsequently annealed to obtain desired composition profiles across the absorber structures for use in photovoltaic devices.

### CROSS-REFERENCE TO RELATED APPLICATION

The present application claims priority to U.S. provisional application Ser. No. 61/297,144 filed Jan. 21, 2010 and entitled “Control of Composition Profiles in Annealed CIGS Absorbers,” which is incorporated by reference herein for all purposes.

### TECHNICAL FIELD

The present disclosure generally relates to the manufacturing of photovoltaic devices, and more particularly, to the use of sputtering in forming multilayer absorber structures that are subsequently annealed to obtain desired composition profiles across the absorber structures for use in photovoltaic devices.

### BACKGROUND

P-n junction based photovoltaic cells are commonly used as solar cells. Generally, p-n junction based photovoltaic cells include a layer of an n-type semiconductor in direct contact with a layer of a p-type semiconductor. By way of background, when a p-type semiconductor is positioned in intimate contact with an n-type semiconductor a diffusion of electrons occurs from the region of high electron concentration (the n-type side of the junction) into the region of low electron concentration (the p-type side of the junction). However, the diffusion of charge carriers (electrons) does not happen indefinitely, as an opposing electric field is created by this charge imbalance. The electric field established across the p-n junction induces a separation of charge carriers that are created as result of photon absorption.

Chalcogenide (both single and mixed) semiconductors have optical band gaps well within the terrestrial solar spectrum, and hence, can be used as photon absorbers in thin film based photovoltaic cells, such as solar cells, to generate electron-hole pairs and convert light energy to usable electrical energy. More specifically, semiconducting chalcogenide films are typically used as the absorber layers in such devices. A chalcogenide is a chemical compound consisting of at least one chalcogen ion (group 16 (VIA) elements in the periodic table, e.g., sulfur (S), selenium (Se), and tellurium (Te)) and at least one more electropositive element. As those of skill in the art will appreciate, references to chalcogenides are generally made in reference to sulfides, selenides, and tellurides. Thin film based solar cell devices may utilize these chalcogenide semiconductor materials as the absorber layer(s) as is or, alternately, in the form of an alloy with other elements or even compounds such as oxides, nitrides and carbides, among others.

Physical vapor deposition (PVD) based processes, and particularly sputter based deposition processes, have conventionally been utilized for high volume manufacturing of such thin film layers with high throughput and yield.

### BRIEF DESCRIPTION OF THE DRAWINGS

FIGS. 1A-1D each illustrate a diagrammatic cross-sectional side view of an example solar cell configuration.

FIGS. 2A and 2B each illustrate an example conversion layer.

FIGS. 3A-3C illustrate plots showing the Ga concentration profile across a respective absorber layer from a back contact to a junction with a buffer layer.

FIG. 4 illustrates a table showing X-ray diffraction data obtained for two example chalcopyrite absorbers.

FIG. 5A illustrates a plot showing quantum efficiency versus wavelength for two example chalcopyrite absorber based photovoltaic cells.

FIG. 5B illustrates a table showing electrical characteristics for two example chalcopyrite absorber based photovoltaic cells.

FIGS. 6A-6B illustrate examples of multilayer structures that can be used in an annealing process to obtain a desired Ga concentration profile across a CIGS absorber. FIG. 6A and FIG. 6B show the same multilayer structures.

FIGS. 7A-7B illustrate examples of multilayer structures that can be used in an annealing process to obtain a desired Ga concentration profile across a CIGS absorber. FIG. 7A and FIG. 7B show the same multilayer structures.

FIGS. 8A-8B illustrate examples of multilayer structures that can be used in an annealing process to obtain a desired Ga concentration profile across a CIGS absorber. FIG. 8A and FIG. 8B show the same multilayer structures.

FIGS. 9A-9B illustrate examples of multilayer structures that can be used in an annealing process to obtain a desired Ga concentration profile across a CIGS absorber. FIG. 9A and FIG. 9B show the same multilayer structures.

FIG. 10 illustrates a plot showing X-ray diffraction data obtained for an example CIGS multilayer structure without annealing.

FIG. 11 illustrates a plot showing X-ray diffraction data obtained for an example CIGS multilayer structure after annealing.

### DESCRIPTION OF EXAMPLE EMBODIMENTS

Particular embodiments of the present disclosure relate to the use of sputtering, and more particularly magnetron sputtering, in forming absorber structures, and particular multilayer absorber structures, that are subsequently annealed to obtain desired composition profiles across the absorber structures for use in photovoltaic devices (hereinafter also referred to as “photovoltaic cells,” “solar cells,” or “solar devices”). In particular embodiments, magnetron sputtering and subsequent annealing are used in forming chalcogenide absorber layer structures. In particular embodiments, such techniques result in chalcogenide absorber layer structures in which a majority of the materials forming the respective structures have chalcopyrite phase. In even more particular embodiments, greater than 90 percent of the resultant chalcogenide absorber layer structures are in the chalcopyrite phase after annealing.

Hereinafter, reference to a layer may encompass a film, and vice versa, where appropriate. Additionally, reference to a layer may encompass a multilayer structure including one or more layers, where appropriate. As such, reference to an absorber may be made with reference to one or more absorber layers that collectively are referred to hereinafter as absorber, absorber layer, absorber structure, or absorber layer structure.

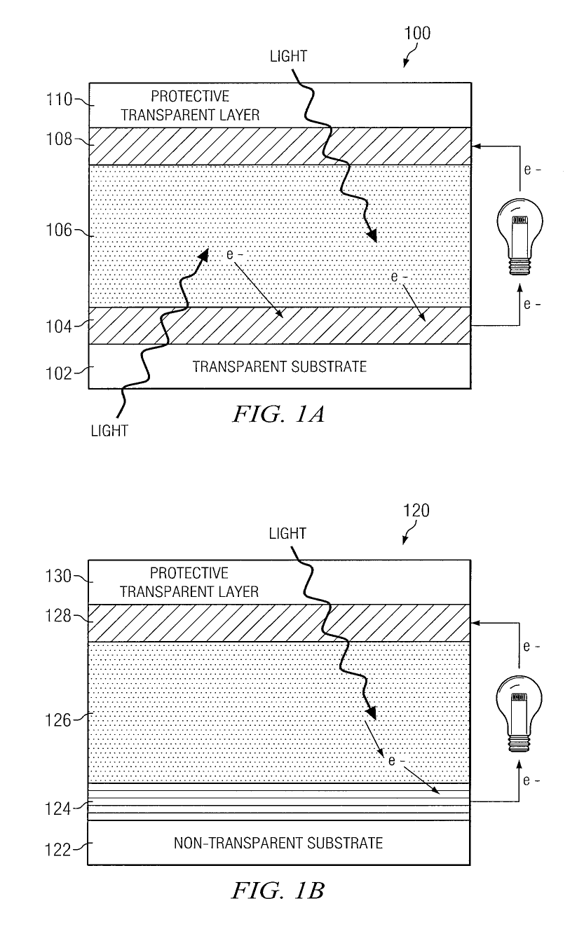

FIG. 1A illustrates an example solar cell 100 that includes, in overlying sequence, a transparent glass substrate 102, a transparent conductive layer 104, a conversion layer 106, a transparent conductive layer 108, and a protective transparent layer 110. In this example solar cell design, light can enter the solar cell 100 from the top (through the protective transparent layer 110) or from the bottom (through the transparent substrate 102). FIG. 1B illustrates another example solar cell 120 that includes, in overlying sequence, a non-transparent substrate (e.g., a metal, plastic, ceramic, or other suitable non-transparent substrate) 122, a conductive layer 124, a conversion layer 126, a transparent conductive layer 128, and a protective transparent layer 130. In this example solar cell design, light can enter the solar cell 120 from the top (through the protective transparent layer 130). FIG. 1C illustrates another example solar cell 140 that includes, in overlying sequence, a transparent substrate (e.g., a glass, plastic, or other suitable transparent substrate) 142, a conductive layer 144, a conversion layer 146, a transparent conductive layer 148, and a protective transparent layer 150. In this example solar cell design, light can enter the solar cell 140 from the top (through protective transparent layer 150). FIG. 1D illustrates yet another example solar cell 160 that includes, in overlying sequence, a transparent substrate (e.g., a glass, plastic, or other suitable transparent substrate) 162, a transparent conductive layer 164, a conversion layer 166, a conductive layer 168, and a protective layer 170. In this example solar cell design, light can enter the solar cell 160 from the bottom (through the transparent substrate 162).

In order to achieve charge separation (the separation of electron-hole pairs) during operation of the resultant photovoltaic devices, each of the conversion layers 106, 126, 146, and 166 are comprised of at least one n-type semiconductor material and at least one p-type semiconductor material. In particular embodiments, each of the conversion layers 106, 126, 146, and 166 are comprised of at least one or more absorber layers and one or more buffer layers having opposite doping as the absorber layers. By way of example, if the absorber layer is formed from a p-type semiconductor, the buffer layer is formed from an n-type semiconductor. On the other hand, if the absorber layer is formed from an n-type semiconductor, the buffer layer is formed from a p-type semiconductor. More particular embodiments of example conversion layers suitable for use as one or more of conversion layers 106, 126, 146, or 166 will be described later in the present disclosure.

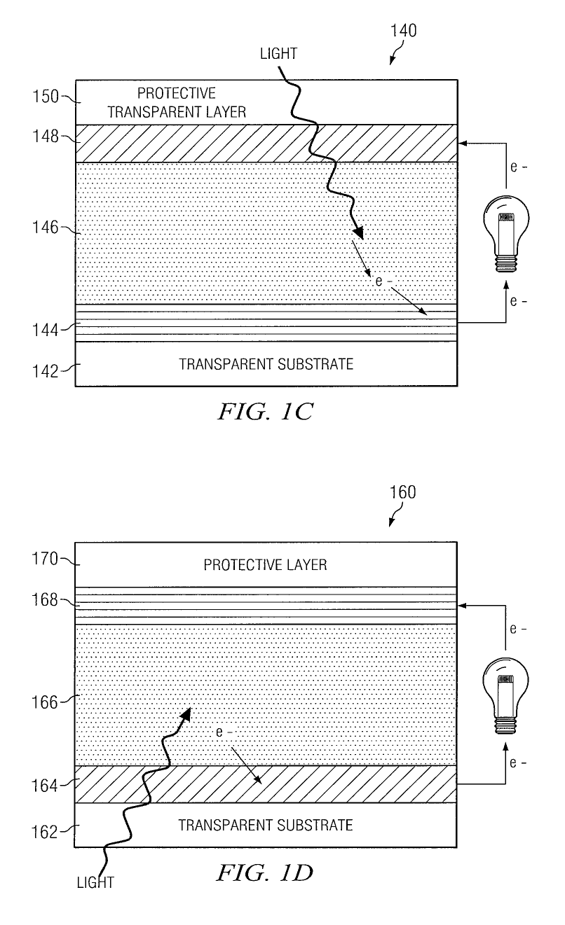

FIG. 2A illustrates an example conversion layer 200 that is comprised of an overlying sequence of n adjacent absorber layers (where n is the number of adjacent absorber layers and where n is greater than or equal to 1) 2021 to 202n (collectively forming absorber layer 202), adjacent to m adjacent buffer layers (where m is the number of adjacent buffer layers and where m is greater than or equal to 1) 2041 to 204m (collectively forming buffer layer 204). In particular embodiments, at least one of the absorber layers 2021 to 202n is sputtered in the presence of a sputtering atmosphere that includes at least one of H₂S and H₂Se. Although FIG. 2A illustrates the buffer layers 204 as being formed over the absorber layers 202 (relative to the substrate or back contact), in alternate embodiments, the absorber layers 202 may be positioned over the buffer layers 204 as, for example, illustrated in FIG. 2B. In particular embodiments, each of the absorber layers 2021 to 202n are deposited using magnetron sputtering.

In particular embodiments, each of the transparent conductive layers 104, 108, 128, 148, or 164 is comprised of at least one oxide layer. By way of example and not by way of limitation, the oxide layer forming the transparent conductive layer may include one or more layers each formed of one or more of: titanium oxide (e.g., one or more of TiO, TiO₂, Ti₂O₃, or Ti₃O₅), aluminum oxide (e.g., Al₂O₃), cobalt oxide (e.g., one or more of CoO, Co₂O₃, or Co₃O₄), silicon oxide (e.g., SiO₂), tin oxide (e.g., one or more of SnO or SnO₂), zinc oxide (e.g., ZnO), molybdenum oxide (e.g., one or more of Mo, MoO₂, or MoO₃), tantalum oxide (e.g., one or more of TaO, TaO₂, or Ta₂O₅), tungsten oxide (e.g., one or more of WO₂ or WO₃), indium oxide (e.g., one or more of InO or In₂O₃), magnesium oxide (e.g., MgO), bismuth oxide (e.g., Bi₂O₃), copper oxide (e.g., CuO), vanadium oxide (e.g., one or more of VO, VO₂, V₂O₃, V₂O₅, or V₃O₅), chromium oxide (e.g., one or more of CrO₂, CrO₃, Cr₂O₃, or Cr₃O₄), zirconium oxide (e.g., ZrO₂), or yttrium oxide (e.g., Y₂O₃). Additionally, in various embodiments, the oxide layer may be doped with one or more of a variety of suitable elements or compounds. In one particular embodiment, each of the transparent conductive layers 104, 108, 128, 148, or 164 may be comprised of ZnO doped with at least one of: aluminum oxide, titanium oxide, zirconium oxide, vanadium oxide, or tin oxide. In another particular embodiment, each of the transparent conductive layers 104, 108, 128, 148, or 164 may be comprised of indium oxide doped with at least one of: aluminum oxide, titanium oxide, zirconium oxide, vanadium oxide, or tin oxide. In another particular embodiment, each of the transparent conductive layers 104, 108, 128, 148, or 164 may be a multi-layer structure comprised of at least a first layer formed from at least one of: zinc oxide, aluminum oxide, titanium oxide, zirconium oxide, vanadium oxide, or tin oxide; and a second layer comprised of zinc oxide doped with at least one of: aluminum oxide, titanium oxide, zirconium oxide, vanadium oxide, or tin oxide. In another particular embodiment, each of the transparent conductive layers 104, 108, 128, 148, or 164 may be a multi-layer structure comprised of at least a first layer formed from at least one of: zinc oxide, aluminum oxide, titanium oxide, zirconium oxide, vanadium oxide, or tin oxide; and a second layer comprised of indium oxide doped with at least one of: aluminum oxide, titanium oxide, zirconium oxide, vanadium oxide, or tin oxide.

In particular embodiments, each of the conductive layers 124, 144, or 168 is comprised of at least one metal layer. By way of example and not by way of limitation, each of conductive layers 124, 144, or 168 may be formed of one or more layers each individually or collectively containing at least one of: aluminum (Al), titanium (Ti), vanadium (V), chromium (Cr), manganese (Mn), iron (Fe), cobalt (Co), nickel (Ni), copper (Cu), zirconium (Zr), niobium (Nb), molybdenum (Mo), ruthenium (Ru), rhodium (Rh), palladium (Pd), platinum (Pt), silver (Ag), hafnium (Hf), tantalum (Ta), tungsten (W), rhenium (Re), iridium (Ir), or gold (Au). In one particular embodiment, each of conductive layers 124, 144, or 168 may be formed of one or more layers each individually or collectively containing at least one of: Al, Ti, V, Cr, Mn, Fe, Co, Ni, Cu, Zr, Nb, Mo, Ru, Rh, Pd, Pt, Ag, Hf, Ta, W, Re, Ir, or Au; and at least one of: boron (B), carbon (C), nitrogen (N), lithium (Li), sodium (Na), silicon (Si), phosphorus (P), potassium (K), cesium (Cs), rubidium (Rb), sulfur (S), selenium (Se), tellurium (Te), mercury (Hg), lead (Pb), bismuth (Bi), tin (Sn), antimony (Sb), or germanium (Ge). In another particular embodiment, each of conductive layers 124, 144, or 168 may be formed of a Mo-based layer that contains Mo and at least one of: B, C, N, Na, Al, Si, P, S, K, Ti, V, Cr, Mn, Fe, Co, Ni, Cu, Zn, Ga, Ge, Se, Rb, Zr, Nb, Mo, Ru, Rh, Pd, Ag, Cs, Hf, Ta, W, Re, Ir, Pt, Au, Hg, Pb, or Bi. In another particular embodiment, each of conductive layers 124, 144, or 168 may be formed of a multi-layer structure comprised of an amorphous layer, a face-centered cubic (fcc) or hexagonal close-packed (hcp) interlayer, and a Mo-based layer. In such an embodiment, the amorphous layer may be comprised of at least one of: CrTi, CoTa, CrTa, CoW, or glass; the fcc or hcp interlayer may be comprised of at least one of: Al, Ni, Cu, Ru, Rh, Pd, Ag, Ir, Pt, Au, or Pb; and the Mo-based layer may be comprised of at least one of Mo and at least one of: B, C, N, Na, Al, Si, P, S, K, Ti, V, Cr, Mn, Fe, Co, Ni, Cu, Zn, Ga, Ge, Se, Rb, Zr, Nb, Mo, Ru, Rh, Pd, Ag, Cs, Hf, Ta, W, Re, Ir, Pt, Au, Hg, Pb, or Bi.

In particular embodiments, magnetron sputtering may be used to deposit each of the conversion layers 106, 126, 146, or 166, each of the transparent conductive layers 104, 108, 128, 148, or 164, as well as each of the conductive layers 124, 144, or 168. Magnetron sputtering is an established technique used for the deposition of metallic layers in, for example, magnetic hard drives, microelectronics, and in the deposition of intrinsic and conductive oxide layers in the semiconductor and solar cell industries. In magnetron sputtering, the sputtering source (target) is a magnetron that utilizes strong electric and magnetic fields to trap electrons close to the surface of the magnetron. These trapped electrons follow helical paths around the magnetic field lines undergoing more ionizing collisions with gaseous neutrals near the target surface than would otherwise occur. As a result, the plasma may be sustained at a lower sputtering atmosphere pressure. Additionally, higher deposition rates may also be achieved.

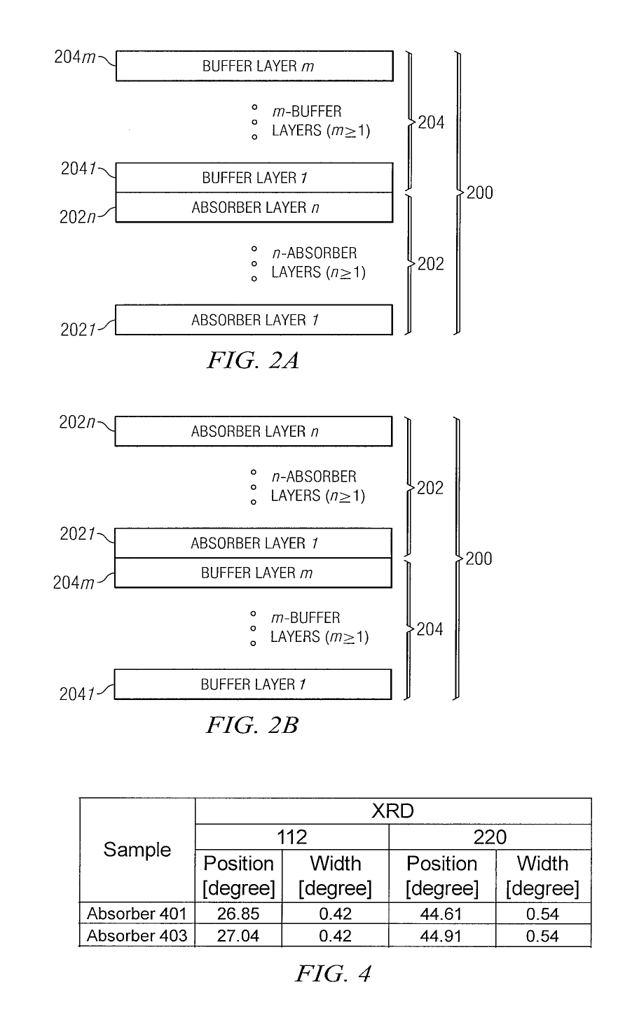

More particular embodiments of absorber layers suitable for use in, for example, conversion layers 106, 126, 146, or 166, as well as methods of manufacturing the same, will now be described with reference to FIGS. 3-9. Copper indium gallium diselenide (e.g., Cu(In₁₋ₓGaₓ)Se₂, where x is less than or equal to approximately 0.7), copper indium gallium selenide sulfide (e.g., Cu(In₁₋ₓGaₓ)(Se_{1-y}S_{y})₂, where x is less than or equal to approximately 0.7 and where y is less than or equal to approximately 0.99), and copper indium gallium disulfide (e.g., Cu(In₁₋ₓGaₓ)S₂, where x is less than or equal to approximately 0.7), each of which is commonly referred to as a “CIGS” material or structure, have been successfully used in the fabrication of thin film absorbers in photovoltaic cells largely due to their relatively large absorption coefficients. In fact, photovoltaic cells having photovoltaic efficiencies greater than or equal to approximately 20% have been manufactured using copper indium gallium diselenide absorber layers.

By way of example, an efficient CIGS based photovoltaic cell has been demonstrated by Repins et. al. (19·9%-efficient ZnO/CdS/CuInGaSe² solar cell with 81·2% fill factor, Ingrid Repins, Miguel A. Contreras, Brian Egaas, Clay DeHart, John Scharf, Craig L. Perkins, Bobby To, Rommel Noufi, Progress in Photovoltaics: Research and Applications, Volume 16 Issue 3, Pages 235-239) using subsequent evaporation of (In,Ga)Se, CuSe, and (In,Ga)Se layers in a temperature range of 350 degrees Celsius to 600 degrees Celsius. However, Repins' process leads to non-uniform Ga concentration across the absorber, high Ga concentration close to the back contact and at the interface with the buffer layer (i.e., the p-n junction), and low Ga concentration in the middle of the absorber (“Required Materials Properties for High-Efficiency CIGS Modules,” Repins et al., NREL/CP-520-46235, July 2009). This Ga composition profile across the CIGS absorber is illustrated in FIG. 3C.

Controlling the Ga concentration and concentration profile across the CIGS absorber is important for maximizing the photovoltaic efficiency of the resultant photovoltaic device. By way of example, assume first that the Ga concentration is constant (does not change) across the CIGS absorber, as illustrated in FIG. 3A. In this case, substitution of Ga for In increases the efficiency of the CIGS absorber for the Ga/(Ga+In) ratio less than approximately 0.4. This is due to the increase in the band gap of the CIGS absorber from 1.04 eV to over 1.3 eV (See M. Gloeckler, J. R. Sites, Band-gap grading in Cu(In,Ga)Se2 solar cells, Journal of Physics and Chemistry of Solid, 66, 1891 (2005), hereinafter “Gloeckle”). In Gloeckle, the author predicted that the partial substitution of Ga for In can increase the efficiency of the CIGS absorber almost 2%. Gloeckle furthermore predicted that the efficiency of the CIGS solar cell will also increase if Ga concentration is higher toward the back contact due to a drift field that will assist minority electron collection and reduced back contact recombination. Increase of Ga concentration close to the back contact can be translated to about 0.7% efficiency gain of the CIGS absorber (See Gloeckle). This Ga profile concentration across the CIGS absorber is termed “back grading” and is shown in FIG. 3B. If Ga concentration is higher toward the back contact of the CIGS absorber and close to the junction with the buffer layer the Ga profile concentration is termed “double grading” as shown in FIG. 3C. The double grading profile increases the CIGS absorber efficiency by approximately 0.3% in comparison to the single grading disclosed in Gloeckle. Increase in Ga concentration at the interface between the absorber and the buffer layer increases the solar cell output voltage. Single and double grading Ga profiles, across the CIGS absorber, are illustrated in FIG. 3B and FIG. 3C, respectively. Thus, to maximize the efficiency of a photovoltaic cell, the Ga concentration in the absorber layer should be higher toward the back contact and at the interface with the buffer layer, and lower in the middle of the absorber (double grading). Furthermore, the Ga concentration has to be larger than zero across the CIGS absorber (see FIG. 3C). In particular embodiments, the Ga/(In+Ga) ratio should be larger than 0 and preferably larger than 0.05 across the CIGS absorber.

Previous attempts to achieve this Ga composition profile by annealing a Cu(In,Ga)(Se,S) layer or a two layer structure consisting of a (In,Ga)Se layer and a CuSe layer have failed due to the preferential diffusion of the In and Ga, which results in a higher Ga concentration close to the back contact and a significantly lower Ga concentration at the interface with the buffer layer that may be close to zero.

However, the present inventors have determined that if a (In,Ga)Se/CuSe multilayer absorber structure (e.g., a first layer of (InₓGa₁₋ₓ)Se adjacent a second layer of CuSe) is sputtered at temperatures below, for example, approximately 300 degrees Celsius, and subsequently annealed at temperatures above, for example, 350 degrees Celsius, the diffusion of In and Ga results in a higher Ga concentration close to the back contact of the absorber and a significantly lower Ga concentration in the interface region of the absorber layer close to the interface with the buffer layer. FIG. 3B illustrates an example composition profile of Ga across an example CIGS absorber achieved with such methods. From the shift of X-ray peaks we find that in this case a very small amount of Ga, if any, is at the interface with the buffer layer.

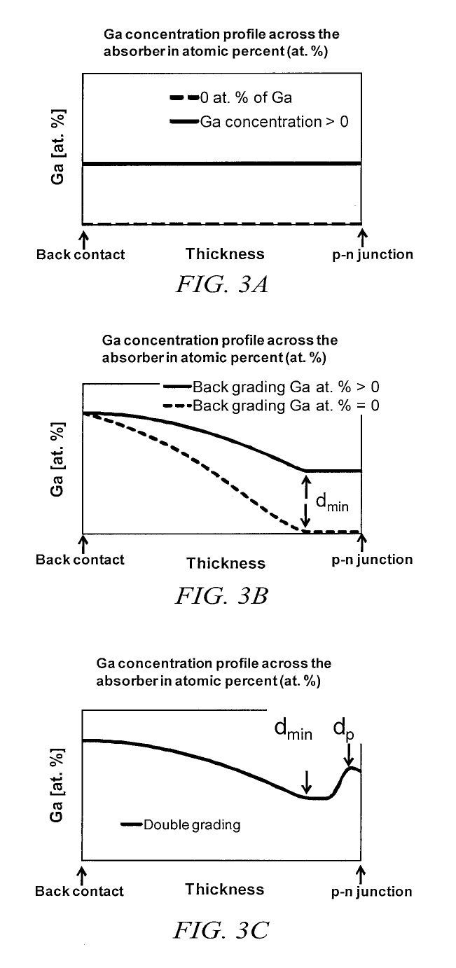

FIG. 4 illustrates a table that shows X-ray diffraction pattern data obtained for two example absorber samples 401 and 403. Absorber 401 may be obtained by annealing a (In,Ga)₂Se₃/CuSe multilayer structure (i.e., the multilayer structure comprises a layer of (InₓGa₁₋ₓ)₂Se₃) and a layer of CuSe) in an atmosphere of H₂S at temperatures over, for example, 500 degrees Celsius. Absorber 403 may be obtained by annealing four pairs of an (In,Ga)₂Se₃/CuSe multilayer structure (i.e., each pair comprises a layer of (InₓGa₁₋ₓ)₂Se₃) and a layer of CuSe) in an atmosphere of H₂S at temperatures over, for example, 500 degrees Celsius. In particular embodiments, the collective total Cu, In and Ga compositions in each of example absorbers 401 and 403 are the same. In a particular embodiment, the (In,Ga)₂Se₃/CuSe multilayer structures of absorbers 401 and 403 are deposited over glass substrates and Mo back contacts. The X-ray data show both of the [112] and [220] peaks of the example absorbers 401 and 403. The [112] and [220] peaks of example absorber 403 are shifted toward the higher angles with respect to the peaks of example absorber 401. Here it should be noted that substitution of Ga for In in CIGS absorbers reduces the spacing between atoms in the CIGS crystal structure therefore shifting the X-ray peaks toward higher angles. Hence, the X-ray diffraction data of FIG. 4 indicates that there is a higher Ga concentration at the surface of absorber 403 than at the surface of absorber 401. Thus, annealing of the two layer (In,Ga)₂Se₃/CuSe structure of absorber 401 results in a steep gradient of Ga concentration where the majority of the Ga is close to the back contact. On the other hand, annealing of the eight layer 4x[(In,Ga)₂Se₃/CuSe] structure, leads to a more uniform Ga concentration and a higher Ga concentration close to the buffer layer. The difference in the Ga profile is illustrated in FIG. 3B.

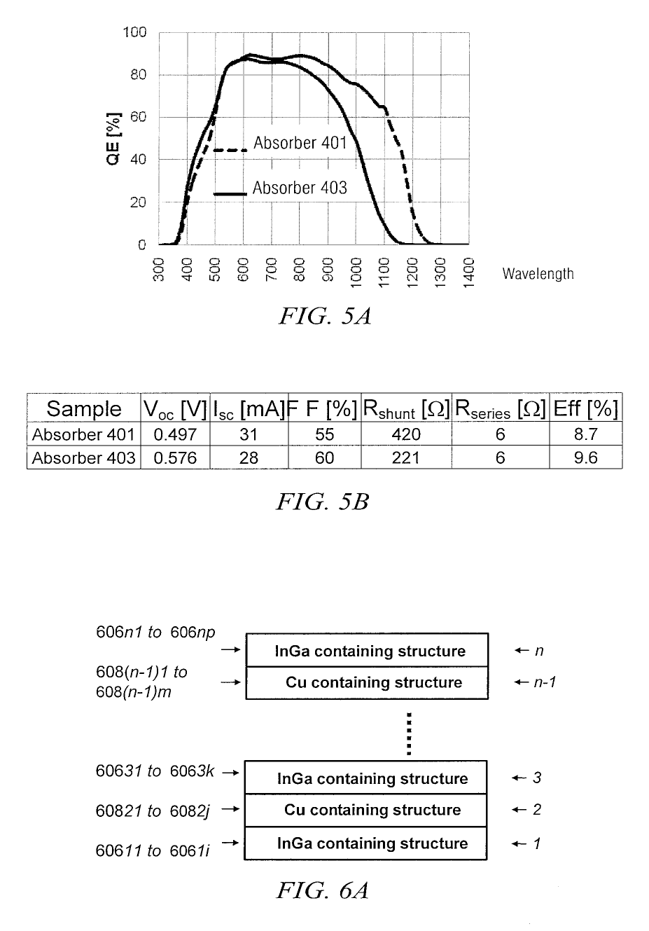

FIGS. 5A-5B show a plot of the quantum efficiency (QE) and a table of current-voltage (I-V) measurements, respectively, of solar cells incorporating absorbers 401 and 403. The quantum efficiency measurement represents the absorption percentage in a solar cell as a function of the wavelength of light used to irradiate the solar cell (e.g., a 90% quantum efficiency at a wavelength of 800 nanometers (nm) means that 90% of the 800 nm wavelength photons irradiating the solar cell are absorbed in the solar cell). The quantum efficiency data of FIG. 5A show that the absorber 401-based solar cell absorbs light up to a 1250 nm wavelength, while the absorber 403-based solar cell absorbs light up to a 1150 nm wavelength. Here it should be noted that substitution of Ga for In in CIGS absorbers increases the band gap of the absorber. As a result, since only photons with energies above the band gap can excite carriers into the conductive band, an addition of Ga in a CIGS absorber will reduce the range of light that can be absorbed in the CIGS absorber. In other words, some of the photons with larger wavelengths, and therefore lower energies, will not be able to excite electrons into the conductive band because of the increase in the band gap due to the Ga presence in CIGS absorbers. Following this logic, absorber 401 has areas with lower Ga concentration than absorber 403 and, thus, can absorb light having higher wavelengths than can absorber 403. On the other hand, absorber 403 has a more uniform Ga distribution resulting in an overall increase of the energy barrier of the band gap. This explains the reduction in the absorption range from 1250 to 1150 nm in the absorber 403-based solar cells and, therefore, the lower output current of this solar cell in comparison to that of the absorber 401-based solar cells, as shown by the table in FIG. 5B. Additionally, the higher Ga concentration close to the buffer layer in the absorber 403-based cell results in higher voltages of this cell in comparison to that of the absorber 401-based solar cells. FIG. 5B also shows that the conversion efficiency, η, of the absorber 403-based cell is larger than that of the absorber 401-based solar cell.

Here it should be additionally noted that the role of H₂S in the annealing of the (In,Ga)₂Se₃/CuSe and 4x[(In,Ga)₂Se₃/CuSe] multilayer structures is important. More specifically, during the annealing, S diffuses at the surface of the CIGS absorber increasing the band gap of the absorber. As this absorber surface (with a higher S concentration) is in direct contact with the buffer layer, this leads to an increase in the voltage of the solar cell.

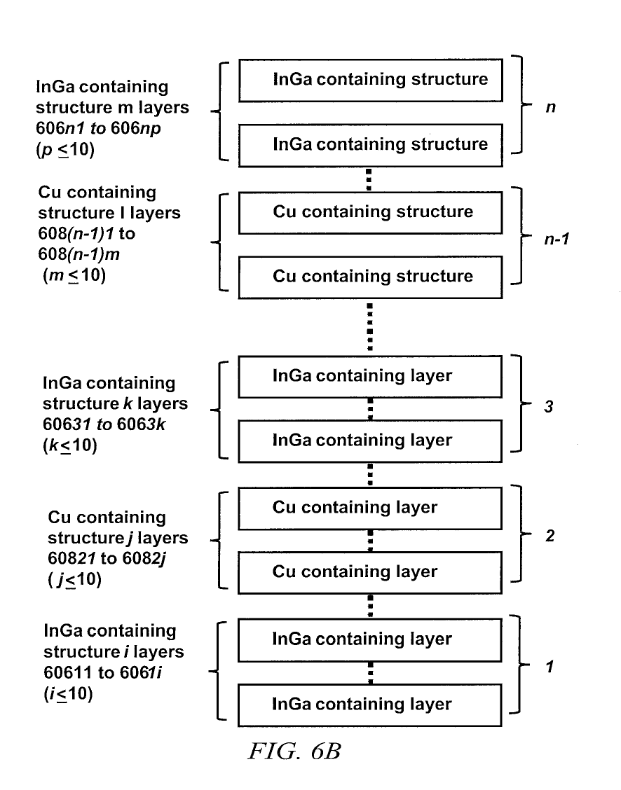

Referring back to FIGS. 5A and 5B, the data obtained for the absorber 401- and absorber 403-based solar cells show that increasing the number of (In,Ga)₂Se₃/CuSe multilayers restricts the Ga diffusion across the respective CIGS absorber during the annealing process. FIGS. 6A and 6B, 7A and 7B, 8A and 8B, and 9A and 9B, show multilayer structures that can be used for controlling the Ga concentration (composition) profile across CIGS absorber during a subsequent annealing process. Generally, the multilayer structures of these Figures include InGa containing structures that are separated by Cu containing structures. In particular embodiments, each InGa containing structure includes up to ten InGa containing layers and each Cu containing structure includes up to ten Cu containing layers. Furthermore, in particular embodiments, the collective total number of both InGa and Cu containing layers may range from 3 to 100.

More particularly, FIGS. 6A and 6B illustrate multilayer absorber structures in which the first and last absorber layers are InGa-containing structures (of one or more InGa-based layers). Even more particularly, FIGS. 6A and 6B illustrate a multilayer structure that is comprised of an overlying sequence of i InGa-containing absorber layers (e.g., where i is greater than or equal to 1 and less than or equal to 10) 60611 to 6061i, j Cu-containing absorber layers (e.g., where j is greater than or equal to 0 and less than or equal to 10) 60821 to 6082j, k InGa-containing absorber layers (e.g., where k is greater than or equal to 0 and less than or equal to 10) 60631 to 6063k, and so on, and in which the second to last structure comprises m Cu-containing absorber layers (e.g., where m is greater than or equal to 1 and less than or equal to 10) 608(n−1)l to 608(n−1)m, and in which the last structure comprises p InGa-containing absorber layers (e.g., where p is greater than or equal to 1 and less than or equal to 10) 606n1 to 606np. It should be noted that, in some embodiments, all InGa-containing layers 606 forming a particular multilayer absorber structure need not have identical composition. Similarly, it should be noted that, in some embodiments, all Cu-containing layers 608 forming a particular multilayer absorber structure need not have identical composition.

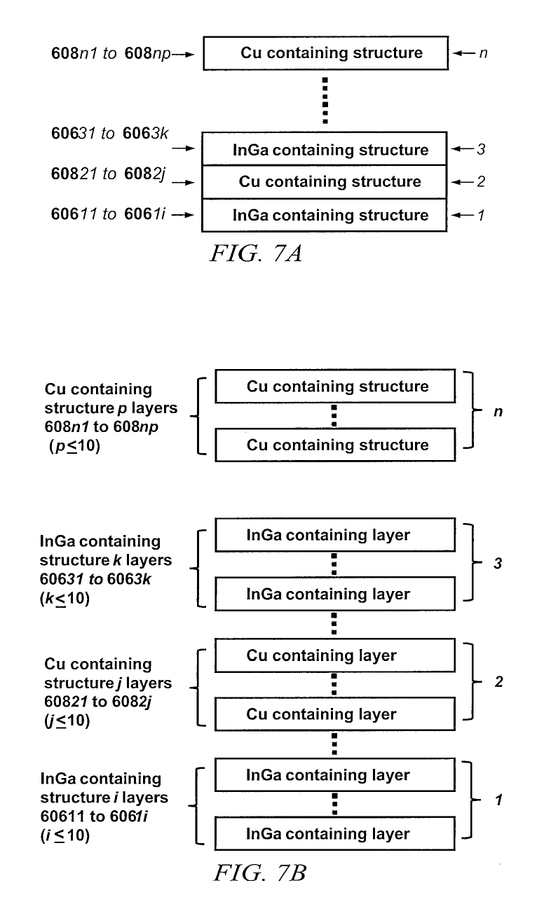

FIGS. 7A and 7B illustrate multilayer absorber structures in which the first deposited absorber structure is a InGa-containing structure (of one or more InGa layers) and the last deposited absorber structure is a Cu-containing structure (of one or more Cu layers). Even more particularly, FIGS. 7A and 7B illustrate a multilayer structure that is comprised of an overlying sequence of i InGa-containing absorber layers (e.g., where i is greater than or equal to 1 and less than or equal to 10) 60611 to 6061i, j Cu-containing absorber layers (e.g., where j is greater than or equal to 0 and less than or equal to 10) 60821 to 6082j, k InGa-containing absorber layers (e.g., where k is greater than or equal to 0 and less than or equal to 10) 60631 to 6063k, and so on, and in which the last structure comprises p Cu-containing absorber layers (e.g., where p is greater than or equal to 1 and less than or equal to 10) 608n1 to 608np. It should be noted that, in some embodiments, all InGa-containing layers 606 forming a particular multilayer absorber structure need not have identical composition. Similarly, it should be noted that, in some embodiments, all Cu-containing layers 608 forming a particular multilayer absorber structure need not have identical composition. For example, the 4x[(In,Ga)₂Se₃/CuSe] absorber structure 403 is simplification of the multilayer structure diagrammatically illustrated in FIGS. 7A and 7B and in which the InGa-containing structure consists of single (In,Ga)₂Se₃ layer and the Cu-containing structure consists of a single CuSe layer.

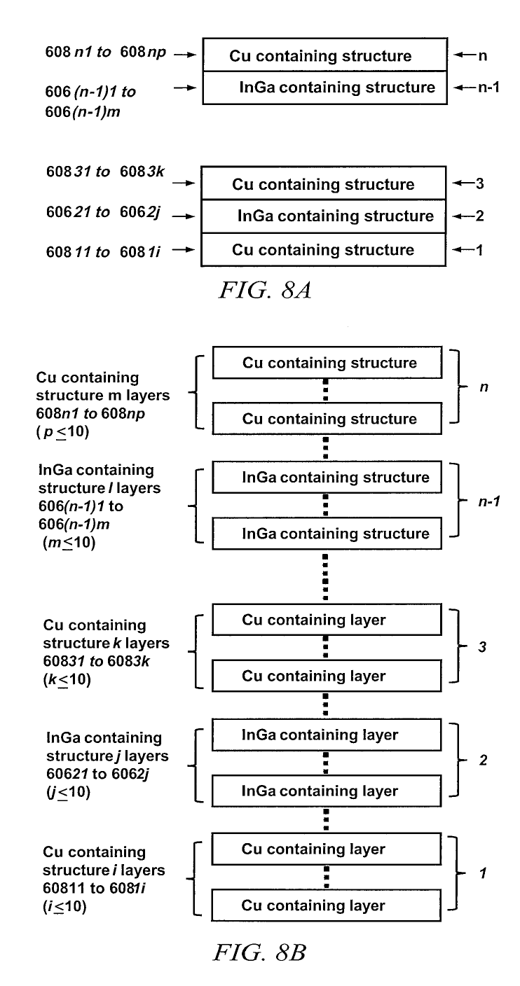

FIGS. 8A and 8B illustrate multilayer absorber structures in which the first and last absorber layers are Cu-containing structures (of one or more Cu-based layers). Even more particularly, FIGS. 8A and 8B illustrate a multilayer structure that is comprised of an overlying sequence of i Cu-containing absorber layers (e.g., where i is greater than or equal to 1 and less than or equal to 10) 60811 to 6081i, j InGa-containing absorber layers (e.g., where j is greater than or equal to 0 and less than or equal to 10) 60621 to 6062j, k Cu-containing absorber layers (e.g., where k is greater than or equal to 0 and less than or equal to 10) 60831 to 6083k, and so on, and in which the second to last structure comprises m InGa-containing absorber layers (e.g., where m is greater than or equal to 1 and less than or equal to 10) 606(n−1)1 to 606(n−1)m, and in which the last structure comprises p Cu-containing absorber layers (e.g., where p is greater than or equal to 1 and less than or equal to 10) 608n1 to 608np. It should be noted that, in some embodiments, all InGa-containing layers 606 forming a particular multilayer absorber structure need not have identical composition. Similarly, it should be noted that, in some embodiments, all Cu-containing layers 608 forming a particular multilayer absorber structure need not have identical composition.

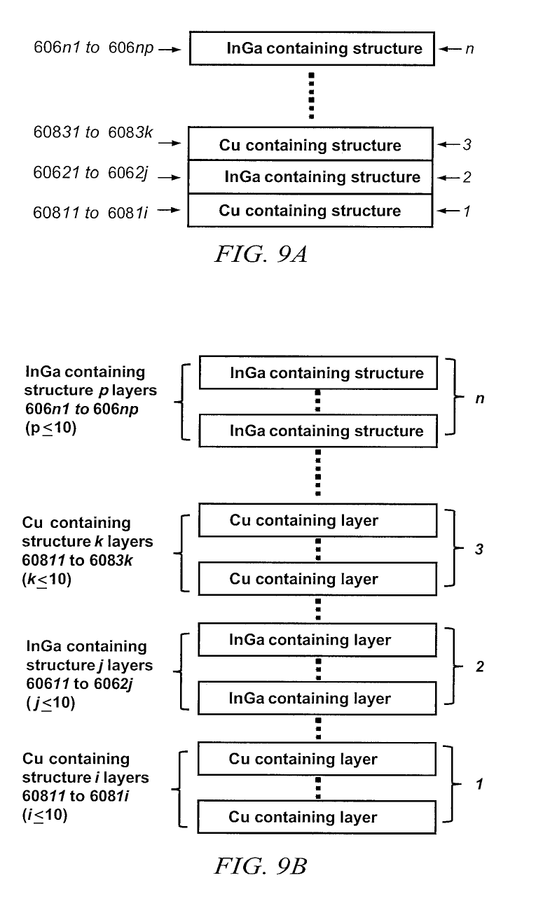

FIGS. 9A and 9B illustrate multilayer absorber structures in which the first deposited absorber structure is a Cu-containing structure (of one or more Cu-based layers) and the last deposited absorber structure is a InGa-containing structure (of one or more InGa-based layers). Even more particularly, FIGS. 9A and 9B illustrate a multilayer structure that is comprised of an overlying sequence of i Cu-containing absorber layers (e.g., where i is greater than or equal to 1 and less than or equal to 10) 60811 to 6081i, j InGa-containing absorber layers (e.g., where j is greater than or equal to 0 and less than or equal to 10) 60621 to 6062j, k Cu-containing absorber layers (e.g., where k is greater than or equal to 0 and less than or equal to 10) 60831 to 6083k, and so on, and in which the last structure comprises p InGa-containing absorber layers (e.g., where p is greater than or equal to 1 and less than or equal to 10) 606n1 to 606np. It should be noted that, in some embodiments, all InGa-containing layers 606 forming a particular multilayer absorber structure need not have identical composition. Similarly, it should be noted that, in some embodiments, all Cu-containing layers 608 forming a particular multilayer absorber structure need not have identical composition.

In FIGS. 6A and 6B, 7A and 7B, 8A and 8B, and 9A and 9B, each InGa- or Cu-containing structure consists of up to ten InGa- or Cu-containing layers, respectively. Of course, each InGa-containing layer contains In and Ga. However, each InGa-containing layer may also contain one or more of: sulfur (S), selenium (Se), and tellurium (Te), as well as one or more of: aluminum (Al), silicon (Si), germanium (Ge), tin (Sn), nitrogen (N), phosphorus (P), copper (Cu), silver (Ag), gold (Au), zinc (Zn), cadmium (Cd), and antimony (Sb). By way of example and not by way of limitation, particular InGa-containing layers may include: (In₁₋ₓGaₓ)_{1-z}(Se_{1-y}S_{y})_{z} (e.g., where 0≦x≦1, 0≦y≦1, 0≦z≦1) and (In_{1-x-α-β-γ}GaₓAl_{α}Zn_{β}Sn_{γ})_{1-z}(Se_{1-y}S_{y})_{z} (e.g., where 0≦x≦1, 0≦α≦0.4, 0≦β≦0.4, 0≦γ≦0.4, α+β+γ≦0.8 0≦y≦1, 0≦z≦1). Similarly, each Cu-containing layer contains Cu, but may also contain one or more of: S, Se, and Te, as well as one or more of: Al, Si, Ge, Sn, N, P, In, Ga, Ag, Au, Zn, Cd, and Sb. By way of example and not by way of limitation, particular Cu-containing layers: Cu₁₋ₓ(Se_{1-y}S_{y})ₓ (e.g., where 0≦x≦1, 0≦y≦1), (Cu_{1-x-α}AgₓAu_{α})_{1-z}(Se_{1-y}S_{y})_{z} (e.g., where 0≦x≦0.4, 0≦α≦0.4, 0≦y≦1, 0≦z≦1), and (Cu_{1-x-α-β-γ}InₓGa_{α}Al_{β}Zn_{γ}Sn_{δ})_{1-z}(Se_{1-y}S_{y})_{z} (e.g., where 0≦x≦0.4, 0≦α≦0.4, 0≦β≦0.4, 0≦γ≦0.4, 0≦δ≦0.4, α+β+γ+δ≦0.8 0≦y≦1, 0≦z≦1).

In particular embodiments, the InGa- and Cu-containing structures described with reference to FIGS. 6A and 6B, 7A and 7B, 8A and 8B, and 9A and 9B, are annealed at temperatures above 350 degrees Celsius in vacuum or in the presence of at least one of: H₂, He, N₂, O₂, Ar, Kr, Xe, H₂Se, and H₂S. In even more particular embodiments, it may be even more desirable to anneal these structures above 500 degrees Celsius.

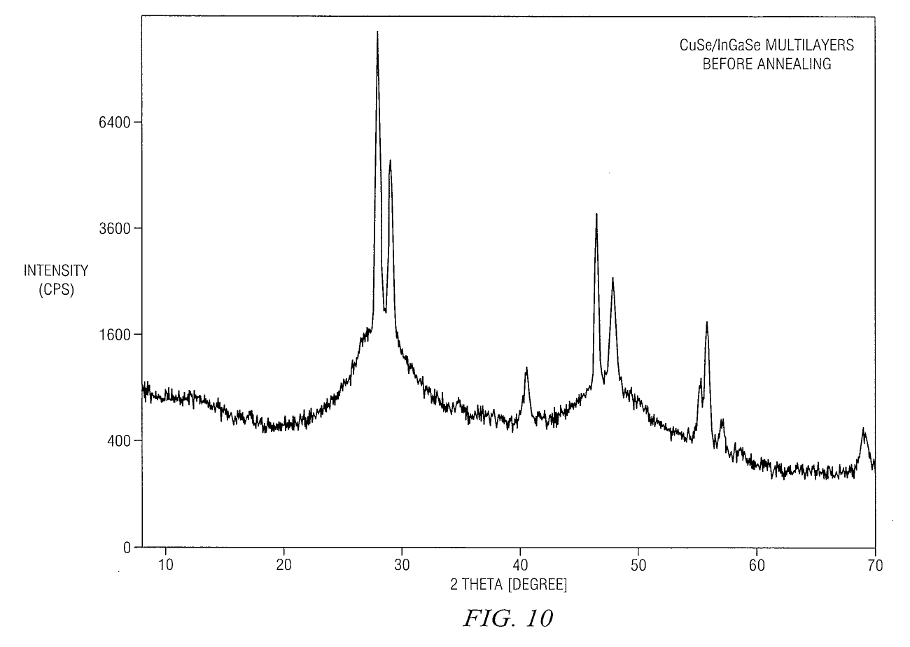

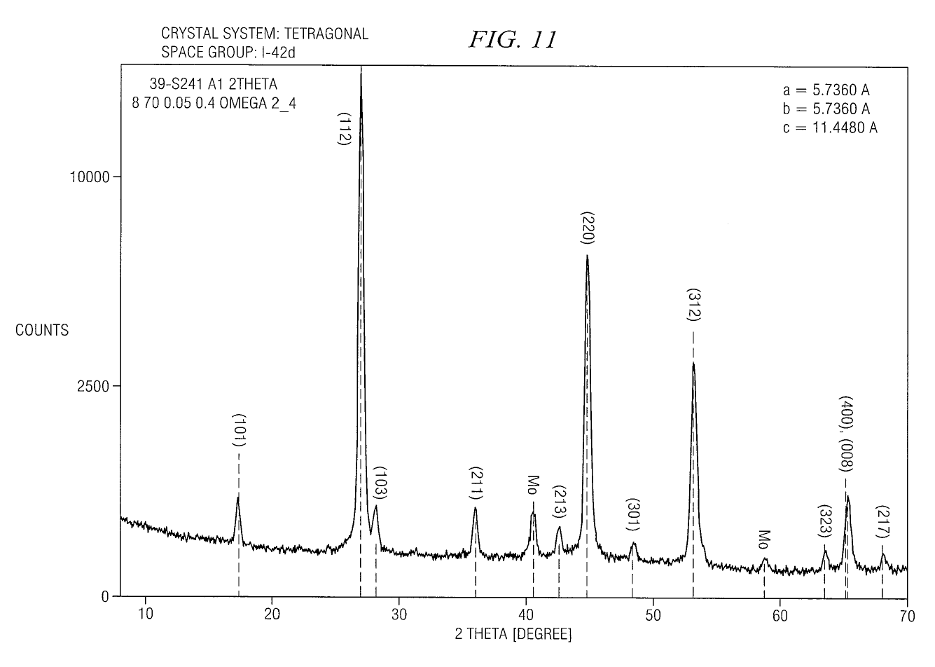

To further illustrate the benefit of annealing according to particular embodiments, FIGS. 10 and 11 illustrate plots showing X-ray diffraction data obtained for example CIGS multilayer structures without annealing and post annealing, respectively. More particularly, the X-ray diffraction plots show the intensity of diffraction (in terms of counts) versus the angle 2θ, where θ is the angle of incidence of the X-ray beam. The particular CIGS structure samples for which the X-ray diffraction data were obtained were comprised of CuSe/InGaSe multilayer structures with Mo back contacts. The peaks in the X-ray diffraction data plots of FIGS. 10 and 11 are due to the constructive interference of X-rays from particular planes of the crystal structure. The numbers enclosed in parentheses in FIG. 11 identify those crystal planes. Thus, the peak at around 27 degrees in FIG. 11 is due to constructive interference of X-rays from (112) planes. As evidenced upon comparison between FIGS. 10 and 11, a different set of peaks is observed after annealing. The peaks, in the annealed CIGS multilayer structure, FIG. 11, correspond to the chalcopyrite phase. This phase is desired in CIGS absorbers due to the high sunlight energy conversion efficiency.

Yet another way to obtain desired chalcopyrite phase is to deposit InGa- and Cu-containing multilayers at temperatures above 350 degrees Celsius and in the presence of at least one of the following gases: H₂, He, N₂, O₂, Ar, Kr, Xe, H₂Se, and H₂S. This is beneficial for increasing production speed as the formation of desired structure is obtained while depositing Cu and In based films.

The present disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend.

What is claimed is:

1. A method comprising:
depositing at least three sets of layers over a conductive layer, wherein at least one of the sets of layers comprises one or more layers that each comprise copper (Cu), wherein at least one of the sets of layers comprises one or more layers that each comprise indium (In) and gallium (Ga), and wherein each set of layers that comprises Cu is in direct contact with at least one set of layers that each comprise In and Ga; and
heating the at least three sets of layers, wherein the heating is performed at a temperature that exceeds approximately 350 degrees Celsius for at least a first time period.

2. The method of claim 1 wherein, during the first time period, the heating is performed either in vacuum or in the presence of at least one of the gases selected from the group consisting of: H₂, He, N₂, O₂, Ar, Kr, Xe, H₂Se, and H₂S.

3. The method of claim 1 wherein depositing at least three sets of layers comprises a sputtering process.

4. The method of claim 1 wherein depositing at least three sets of layers is performed at temperatures below 300 degrees Celsius.

5. The method of claim 4 wherein at least one of the sets of In—Ga layers comprises an (In,Ga)Se layer, and wherein at least one of the sets of Cu layers comprises of a CuSe layer.

6. The method of claim 5 wherein the heating is performed in the presence of H₂S gas.

7. The method of claim 5 wherein the depositing of the at least three sets of layers is performed at temperatures above 350 degrees Celsius and in the presence of at least one of the following gases: H₂, He, N₂, O₂, Ar, Kr, Xe, H₂Se, and H₂S.

8. A photovoltaic cell, comprising:
a conductive layer;
at least three sets of chalcogenide absorber layers deposited over the conductive layer, wherein at least one of the sets of layers comprises one or more layers that each comprise copper (Cu), wherein at least one of the sets of layers comprises one or more layers that each comprise indium (In) and gallium (Ga), and wherein each set of layers that comprises Cu is in direct contact with at least one set of layers that each comprise In and Ga; and
wherein greater than 90 percent composition of the chalcogenide absorber layers are in the chalcopyrite phase.

9. The photovoltaic cell of claim 8 further comprising one or more buffer layers adjacent deposited adjacent to the at least three sets of chalcogenide absorber layers.

10. The photovoltaic cell of claim 8 further comprising a second conductive layer disposed over the at least three sets of chalcogenide absorber layers.

11. The photovoltaic cell of claim 9 comprising a second conductive layer disposed over the at least three sets of chalcogenide absorber layers and the one or more buffer layers.

12. The photovoltaic cell of claim 11 wherein at least one of the first and second conductive layers is transparent.
